(19) United States
(12) Patent Application Publication
(10) Pub. No.: US 2012/0045855 A1
(43) Pub. Date: Feb. 23, 2012

(54) POSITION-SENSITIVE METROLOGY SYSTEM

(76) Inventors: Markus E. Beck, Scotts Valley, CA (US); Erel Milshtein, Cupertino, CA (US)

(21) Appl. No.: 13/212,806

(22) Filed: Aug. 18, 2011

Related U.S. Application Data
(60) Provisional application No. 61/375,714, filed on Aug. 20, 2010.

(51) Int. Cl. H01L 21/66; G01J 3/44; G01R 27/08; G01J 4/00; G01N 21/59; G01J 3/28; G01T 1/36; G01N 21/55

(52) U.S. Cl. 438/16; 73/865.8; 378/83; 356/301; 356/445; 356/364; 356/432; 356/326; 324/691; 257/E21.53

(57) ABSTRACT

A metrology system for analyzing a semiconductor device on a substrate can include a metrology sensor.

This application claims priority under 35 U.S.C. §119(e) to Provisional Application No. 61/375,714, filed on Aug. 20, 2010, which is hereby incorporated by reference in its entirety.

### TECHNICAL FIELD

This invention relates to a metrology system for analyzing a semiconductor device on a substrate.

### BACKGROUND

Manufacturing a photovoltaic module can include a multi-stage deposition process to form a multi-layer structure. The accuracy of post-deposition metrologies at various stages of the manufacturing process can be affected by the discontinuous nature of a given layer in the device structure. For example, measurement of the film composition and thickness by x-ray fluorescence (XRF) can be impacted by the matrix of all layers probed by the incident x-ray radiation. Other measurement methods, such as photoluminescence or Raman spectroscopy, can be affected as well by the layer inconsistency.

### DESCRIPTION OF DRAWINGS

FIG. 1 is a diagram illustrating a metrology system.

FIG. 2 is a diagram illustrating a metrology system.

FIG. 3 is a diagram illustrating a metrology system.

FIG. 4 is a diagram illustrating a photovoltaic device.

FIG. 5 is a diagram illustrating a photovoltaic device.

FIG. 6 is a diagram illustrating a photovoltaic device manufacturing process.

FIG. 7 is a diagram illustrating a metrology system.

FIG. 8 is a diagram illustrating a metrology system.

FIG. 9 is a diagram illustrating a metrology system.

FIG. 10 is a diagram illustrating a metrology system.

FIG. 11 is a flow chart illustrating an operation process of a metrology system.

FIG. 12 is a flow chart illustrating a manufacturing process of a photovoltaic device.

### DETAILED DESCRIPTION

Photovoltaic devices can include multiple layers formed on a substrate (or superstrate). Copper indium gallium diselenide (CIGS) based photovoltaic devices can be made from high temperature vacuum processes, such as co-evaporation, reaction of stacked elemental layers, or selenization of metal precursors. For example, a photovoltaic device can include a transparent conductive oxide (TCO) layer, a buffer layer, a semiconductor layer, and a conductive layer formed adjacent to a substrate. The semiconductor layer can include a semiconductor window layer and a semiconductor absorber layer, which can absorb photons. The semiconductor absorber layer can include CIGS. Each layer in a photovoltaic device can be created (e.g., formed or deposited) by any suitable process and can cover all or a portion of the device and/or all or a portion of the layer or substrate underlying the layer. For example, a “layer” can mean any amount of any material that contacts all or a portion of a surface.

Semiconductor device fabrication can be a process having a multiple-step sequence of photographic, physical and chemical processing steps during which semiconductor device are gradually created on a wafer or substrate. Therefore, semiconductor device can have multi-layer structure. To form desired features, semiconductor device fabrication can involve lithographic chemical etch or photoresist lift-off as well as laser or mechanical scribing. As a result, the multi-layer structure can have more than one discontinuous layer. The accuracy of post-deposition metrologies at various stages of the manufacturing process can be affected by the discontinuous nature of a given layer in the device structure. For example, measurement of the film composition and thickness by x-ray fluorescence (XRF) can be impacted by the inconsistency of all layers probed by the incident x-ray radiation. Other measurement methods, such as photoluminescence or Raman spectroscopy, can be affected as well by the layer inconsistency.

Metrology systems have been used in semiconductor manufacturing, such photoluminescence, Raman spectroscopy, and X-ray fluorescence. For example, X-ray fluorescence (XRF) measurement is used as a non-destructive method for testing semiconductor device. XRF is a well-known technique for determining the elemental composition of a sample and X-ray fluorescence uses radiation beams to probe small features. XRF analyzers generally include an X-ray source, which irradiates the sample, and an X-ray detector, for detecting the X-ray fluorescence emitted by the sample in response to the irradiation. There are different configurations of XRF measurement device. For example, XRF systems can be:
1—Large beam size systems probing bulk averages over spots of large diameter. These are useful for measurement of large samples where averaging over a significant surface area and bulk volume are acceptable.
2—Collimated XRF systems. The broad x-ray radiation from the source can be narrowed-down by cutting off a significant portion of the beam using a collimator. The latter can be shaped as a hole of a rectangle/square of a suitable size allowing measuring smaller features.
3—Optically focused XRF systems. Lenses can be used to actually focus the x-rays from the x-ray source onto the sample. The lenses can be polycapillary glass structures with hundreds to thousands of micrometer sized channels where the angle of total reflection can be used to focus the x-rays onto spots with a diameter in hundreds to tens of microns. The system can offer the capability to acquire faster spectra due to higher x-ray fluxes on the sample and probe smaller areas/features.

For a semiconductor device with multi-layer structure, X-ray fluorescence (XRF) measurement can be used to determine layer composition and feature size. However, the accuracy of X-ray fluorescence (XRF) measurement can be affected by the discontinuous nature of a given layer in the device structure.

Thus, if the composition and/or thickness of a semiconductor device on a substrate (e.g. glass) is to be determined accurately, the incident excitation beams of XRF must avoid probing inconsistent areas of the semiconductor device. A metrology system and related method for analyzing a semiconductor device are developed with capabilities of positioning the XRF measurement spot on an area of consistent layer sequence. The system can include two sensor modules: an optical sensor module can scan the semiconductor device surface to determine a measurement region with consistent layer sequence; a metrology sensor module can then be positioned to measure the correct region to obtain accurate layer composition and element concentration.

In one aspect, a metrology scanner for analyzing a material surface can include a position identification module configured to inspect a material surface to identify a measurement position and an analytical tool adjacent to the position identification configured to take an analytical measurement at the measurement position.

The position identification module and the analytical tool module can be mounted on an adjustable mounting member to adjust the positions position identification module and analytical tool. The position identification module and the analytical tool module can be positioned on separate axes. The metrology scanner can include a control module for reading an output of the position identification module and moving the analytical tool to the measurement position. The position identification module can be configured to scan a material surface and identify a measurement position proximate to a consistent material surface.

In another aspect, a metrology system for analyzing a material surface can include an object position configured to position an object comprising a surface at least partially coated with a material, a position identification module configured to inspect a material surface to identify a measurement position, and an analytical tool adjacent to the position identification configured to take an analytical measurement at the measurement position and adjustable mounting member. The analytical tool can be mounted on the adjustable mounting member to adjust the positions of the analytical tool. The metrology system can include a conveyor for transporting an object to the object position.

The position identification module can be mounted on the adjustable mounting member to adjust the positions of the position identification module. The position identification module can be mounted on a second adjustable mounting member to adjust the positions of the position identification module. The metrology system can include a control module for reading an output of the position identification module and positioning the analytical tool in a position to take a measurement in the measurement position.

The analytical tool can include a source for generating a radiation to illuminate a region of a surface located at the object position, a sensor for measuring the radiation reemitted from a surface located at the object position, and a processing unit for analyzing the radiation measurement and outputting material information based on the radiation measurement. The position identification module can include an optical source that generates a probe beam capable of being directed at the measurement position. The position identification module can include a photodiode or photo-multiplier to convert an optical signal from the measurement position to electrical signals for processing. The position identification module can include a charge-coupled device with a resolution sufficient for inspecting the surface of an object in the object position.

The analytical tool can include an X-ray source for directing X-rays to the measurement position of an object at the object position. The secondary X-rays can be emitted from the measurement position after an object positioned at the object position is excited by the X-ray source. The analytical tool can include a detector for detecting the secondary X-rays emitted from the measurement position and an analyzing unit for analyzing the detector measurements to obtain an element concentration based on the secondary X-rays. The detector can include at least one detector selected from the group containing PIN diode, Si (Li) detector, Ge (Li) detector, silicon drift detector. The analytical tool can include an energy dispersive spectrometer. The analytical tool can include a wavelength dispersive spectrometer.

The analytical tool can include at least one sensor selected from the group consisting Raman spectrometer, reflectometer, ellipsometer, transmission/absorption measurement device, or resistivity sensor. The analytical tool can be configured to take a measurement from a semiconductor-coated surface positioned at the measurement position. The analytical tool can be configured to take a measurement from a surface positioned at the measurement position, wherein the surface is at least partially coated with copper indium gallium diselenide. The analytical tool can be configured to take a measurement from a surface positioned at the measurement position, wherein the surface is at least partially coated with cadmium telluride.

The position identification module can include an optical assembly, optical source, and optical sensor to collect optical reflection from a semiconductor device positioned at the object position. The position identification module can include an optical assembly, optical source, and optical sensor to collect the light emitted from an object positioned at the object position. The position identification module can include an optical assembly, optical source, and optical sensor to collect the light transmitted through an object positioned at the object position. The position identification module can include a spectrometer to parse light into component wavelengths. The metrology system can include a feed-back control loop, wherein the system can adjust a material deposition process based on a measurement taken at the measurement position.

The metrology system can include an enclosure, wherein the first sensor module and the second sensor module can be positioned within the enclosure. The metrology system can be configured to receive an object in a horizontal orientation from an inert atmosphere and return the object to the inert atmosphere for a following process upon completion of the measurements. The metrology system can be configured to receive an object in a horizontal orientation from a controlled atmosphere and return the object to the controlled atmosphere for a following process upon completion of the measurements, wherein the controlled atmosphere comprises nitrogen and argon. The controlled atmosphere can be temperature and moisture controlled.

The position identification module can include at least two sensors and the measurements of the sensors can be averaged to determine the measurement position. The position identification module can be used in conjunction with a patterning recipe to determine the measurement position. The position identification module can include an optical source for generating an optical radiation to illuminate a region of a surface located at the object position, and a sensor for measuring the optical radiation reflected from a surface located at the object position. The sensor can include at least one charge-coupled device. The source can include a single-wavelength or wide band source. The position identification module can include a laser scanner with a signal analysis module. The laser scanner can generate a laser beam to scan the material surface. The signal analysis module can correlate the object position to a reflection of the laser beam.

In another aspect, a method of manufacturing a photovoltaic device can include providing a first photovoltaic device layer on a substrate, providing a second photovoltaic device layer adjacent to the first semiconductor layer, wherein at least one of the photovoltaic device layers is discontinuous, inspecting a surface of the photovoltaic device layers to determine a measurement region with consistent layer sequence, and measuring the measurement region of the photovoltaic device to obtain material property information of the photovoltaic device.

The method can include transporting the substrate on a conveyor. Inspecting a surface of the photovoltaic device layers can include generating a radiation to illuminate a region of the surface of the photovoltaic device layers, measuring the absorption or reflection of the radiation in the photovoltaic device layers, and analyzing the measurement to obtain the structural information of the photovoltaic device layers to determine the measurement region.

Measuring the measurement region of the photovoltaic device can include obtaining at least one of layer thickness, layer composition, sheet resistivity and element concentration of the photovoltaic device. Measuring the measurement region of the photovoltaic device can include measuring a transmitted or reflected signal from the measurement region of the photovoltaic device by at least one sensor selected from the group consisting Raman spectrometer, reflectometer, ellipsometer, or transmission/absorption measurement device. Measuring the measurement region of the photovoltaic device comprises contacting the measurement region of the photovoltaic device with a resistivity sensor. The method can include transporting the photovoltaic device in an inert gas ambient. The photovoltaic device can include copper indium gallium diselenide. The photovoltaic device can include cadmium telluride. The photovoltaic device can include at least two layers of semiconductor material and at least one layer is discontinuous.

In some embodiments, the metrology system can have a metrology scanner installed on-line in a photovoltaic module manufacturing tool. The metrology scanner can have two or more sensor heads mounted on a gantry. A control module can manage the movement of sensor heads on X and Y direction: an optical sensor can probe the semiconductor device surface to find a measurement region. When a measurement region with consistent layer sequence is found, metrology sensor can position its probe spot to the measurement region.

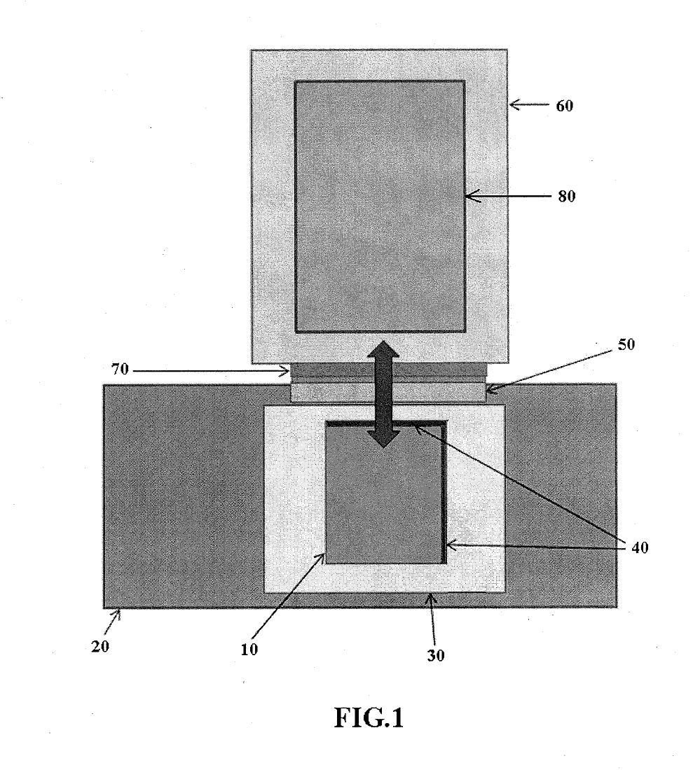

Referring to FIG. 1, a position-sensitive metrology system can receive an object such as substrate 10 in a horizontal orientation from nitrogen-sleeve 20 downstream of the previous deposition tool, collects the measurement data, and returns substrate 10 to nitrogen-sleeve 20 upon completion of the measurements for the subsequent manufacturing process. The metrology system can be connected to nitrogen-sleeve 20 via isolation valve port 50. The metrology system can include sealed enclosure 60 to create and maintain its own N₂ ambient as not to disturb the N₂ atmosphere existing inside nitrogen-sleeve 20. Substrate 10 can have a semiconductor device formed on it. Substrate 10 can be transported from transfer table 30 to an object position where it will be positioned during scanning, such as scan table 80. The metrology system can include interface plate 70 adjacent to isolation valve port 50. Transfer table 30 can have alignment reference edges 40 to align substrate 10.

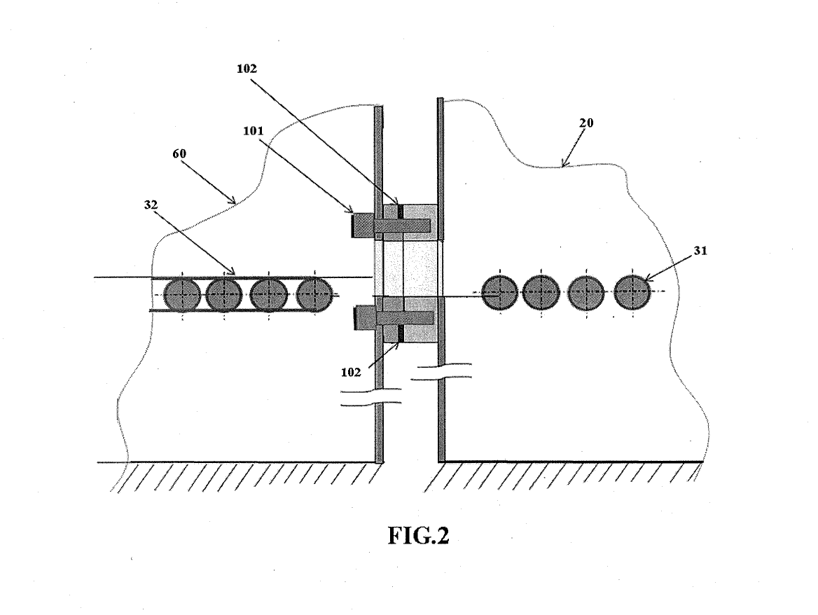

Referring to FIG. 2, the metrology system can have seal 102 with measurement tool and a blank flange. Transfer belt or roller 32 can be positioned within enclosure 60 for transporting substrate 10 (not shown) in/out of the metrology system. Member 101 can be attached to seal 102 to provide access to bolts. Transfer table conveyor 31 can be included to transport transfer table 30 (not shown) to nitrogen-sleeve 20.

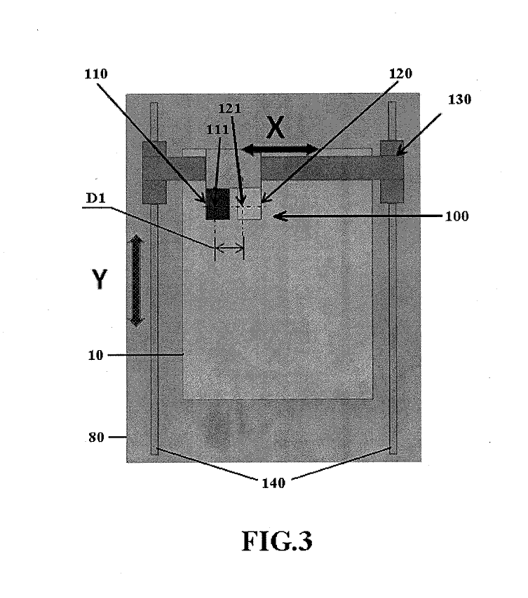

Referring to FIG. 3, metrology scanner 100 can have two sensor heads (110 and 120) mounted on same gantry 130. First sensor head 110 can include a position identification module capable of identifying a position on a surface of an object. For example, first sensor head 110 can scan a material surface of an object. The object can be any object and can include a material coating. The object can include a planar object. The object can include substrate 10. The object can be coated with any suitable material, such as one or more semiconductor layers. The semiconductor layer can include semiconductor materials employed in photovoltaic devices. For example, the semiconductor layer can include copper indium gallium (di)selenide, cadmium telluride, or silicon, or any other suitable material. First sensor head 110 can scan a material surface of the semiconductor material to identify a measurement position. First sensor head 110 can include any suitable position identification tool or combination of tools. For example, first sensor head 110 can include an optical sensor. First sensor head 110 can identify structural changes in a material surface. For example, first sensor head 110 can identify areas of discontinuous material coating or significant contours in the material surface. First sensor head 110 can identify the location of a scribe provided in a material. First sensor head 110 can also identify a measurement position having a consistent material surface suitable for a material measurement by second sensor head 120.

Second sensor head 120 can include any suitable analytical tool or combination of analytical tools. For example, sensor head 120 can include any suitable spectrometer which can be configured to detect optical radiation reemitted from a material (such as a semiconductor material) on the surface of substrate 10. The optical radiation can then be analyzed and information about the material surface, including composition and structural information can be determined. In some embodiments, sensor head 120 can include a mechanical probe making contact to the sample. For example, sensor head 120 can include a 4-point resistivity probe.

A control module (not shown) for the metrology system can manage positioning substrate 10 on scan table 80. Further, the control module can manage the movement of sensor heads 110 and 120 on X and Y direction. Gantry 130 can move on trails 140 for positioning sensor heads 110 and 120 to measurement regions. For example, optical sensor 110 can probe the semiconductor device surface to find a measurement region. Optical sensor 110 can have its own probe spot 111. When a measurement region with consistent layer sequence is found, metrology sensor 120 can position to its own probe spot 121 to the measurement region. The distance D1 between optical sensor 110 and metrology sensor 120 can be in any suitable range, such as less than 200 millimeter, 100-200 millimeter, or less than 100 millimeter.

The metrology system can be used in many semiconductor device manufacturing types, such as a photovoltaic module manufacturing process. Laser scribing is used as one of photovoltaic module manufacturing steps as it is enabling high-volume production of thin-film devices, surpassing mechanical scribing methods in quality, speed, and reliability.

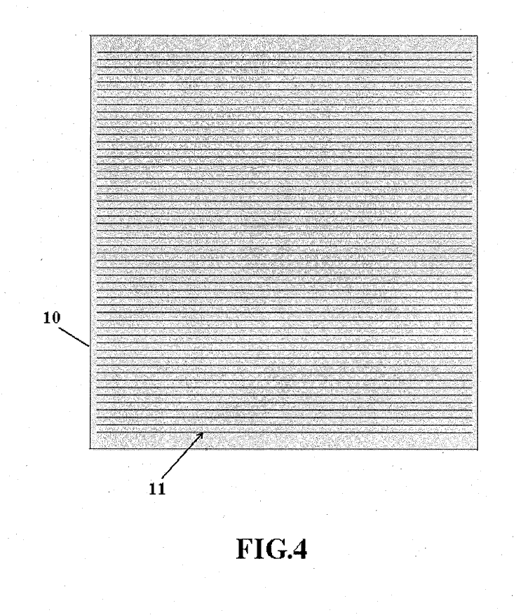

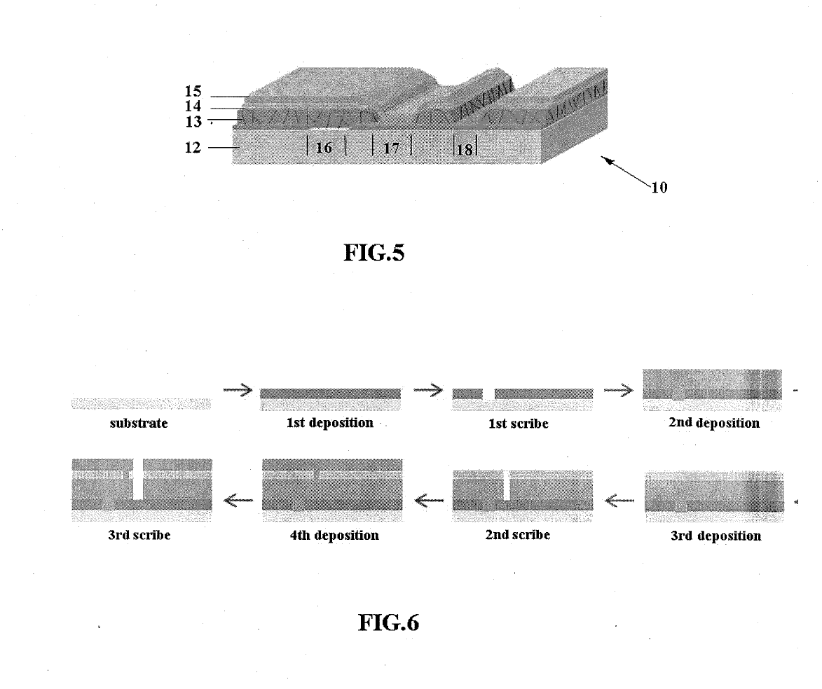

As a result, referring to FIG. 4, scribing trenches 11 on photovoltaic module 10 can be closely spaced. All of scribing trenches 11 shows a discontinuous nature of a given layer in photovoltaic module 10. Without a proper probing and control mechanism, it is difficult to accurately measure layer composition and element concentration of photovoltaic module 10.

For example, for glass-superstrate photovoltaic module, each photovoltaic module starts off as a sheet of glass as a glass superstrate. Referring to FIG. 4, photovoltaic module can have multiple device layers (13, 14, and 15) formed on substrate 12. Three laser scribing processes can leave inconsistent regions (16, 17, and 18) in photovoltaic module 10.

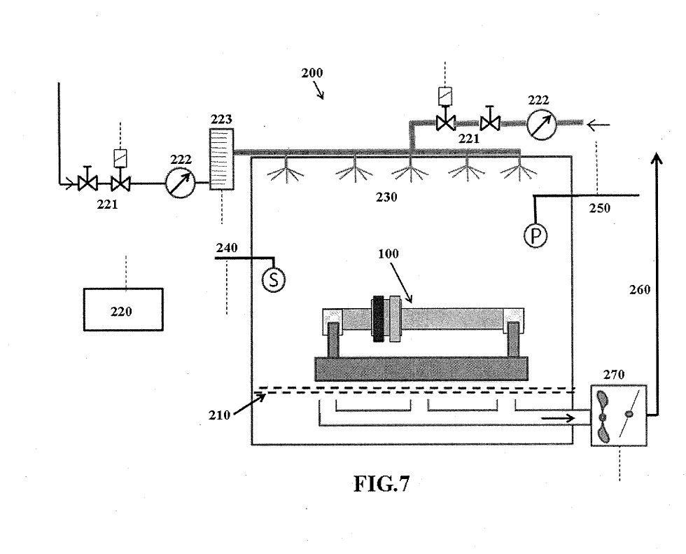

Referring to FIG. 6, for glass-substrate photovoltaic module, each photovoltaic module starts off as a sheet of glass as a glass substrate. The first manufacturing step is to deposit a continuous, uniform thin metal (Al or Mo) layer that forms the back electrodes (contacts). This can be followed by a scribe process called 1^{st} scribe, which scribes through the entire layer thickness. The next step can be deposition of p- and n-type semiconductor materials (2^{nd} and 3^{rd} deposition steps), again followed by a scribing step, called 2^{nd} scribe, which completely cuts through the semiconductor layer. The final deposition is a deposition of a continuous, uniform layer of TCO (transparent conductive oxide), which will form the front electrodes (contacts). These are patterned using a third scribe process, called 3^{rd} scribe.

In some embodiments, the first manufacturing step is to deposit a continuous, uniform layer of TCO (transparent conductive oxide), which will form the front electrodes (contacts). This can be followed by a scribe process called 1^{st} scribe, which scribes through the entire layer thickness. The next step can be vapor deposition of p- and n-type semiconductor materials, again followed by a scribing step, called 2^{nd} scribe, which completely cuts through the silicon layer. The final deposition is the thin metal (Al or Mo) layer that forms the rear electrodes (contacts). These are patterned using a third scribe process, called 3^{rd} scribe.

To prevent inaccurate data generation, measurement spot (121 in FIG. 3) needs to be placed on an area of consistent layer sequence. For example, if the distance between 1^{st} scribes is at the order of 3 to 6 mm and measurement spot (121 in FIG. 3) is at the order of 1 to 3 mm in diameter, careful placement of the measurement spot is required. Similarly, if the 2^{nd} scribe interval is at the order of 3 to 6 mm with a measurement spot (121 in FIG. 3) diameter of 1 to 3 mm, it needs careful alignment to position the measurement area away from the 1^{st} scribe and 2^{nd} scribe locations.

Referring to FIG. 7, metrology scanner 100 can be installed on-line in a photovoltaic module manufacturing tool 200. Manufacturing tool 200 can include adjustable open floor 210. Manufacturing tool 200 can include nitrogen control box 220, on-off valves 221, regulators 222, flow meter 223, and shower outlets or nozzles 230 to create and control nitrogen ambient for manufacturing and measurement process. Manufacturing tool 200 can include pressure sensor 250, oxygen sensor 240, fan and valve 270, and exhaust 260.

To determine the measurement spot, transmitted light or reflected light can measured to locate the inconsistent regions (16, 17, and 18 in FIG. 4). In either case, the bandgap of the material can be used to select a suitable wavelength of the position identification module. For example, if a semiconductor on a metal film which is structured and on a glass substrate, the semiconductor will be transparent above a given wavelength while the metal is typically opaque in this region and the glass is again transparent. This combination (e.g. copper indium gallium diselenide/mo/soda-lime glass) can allow either reflection or transmission measurements for an inconsistent region. For reflection, the opaque metal film (e.g. Mo) needs to reflect sufficient light of the wavelength being employed—typically in near infrared (NIR) region above the bandgap of copper indium gallium diselenide (approx. 1 eV) for the copper indium gallium diselenide/mo/soda-lime glass application. In some embodiments, a position identification module can use visible light and a CCD type camera.

For this metrology system, two modes of operation can be employed to determine the location of the 1st, 2nd and 3rd scribe lines. For a copper indium gallium diselenide (CIGS) photovoltaic module with a Mo back contact on a glass substrate, reflective or transmitted light can be used. The bandgap of the copper indium gallium diselenide of typical compositions used in photovoltaic module varies in the 1000 nm to 1150 nm range. Hence, transmission increases in the near-infrared (NIR) and a suitable light source (e.g. light-emitting diode (LED) or laser in the 700 to 1200 nm range) can be used to illuminate the sample through the glass with the optical sensor on the opposite side.

Similarly, a reflective measurement from the glass side can be employed using light in the visible to near-infrared region. Finally, using light in the near-infrared region from the top copper indium gallium selenide (CIGS) side can be used for reflective mode measurements.

In some embodiments, to increase signal-to-noise and detection with high throughput, a pulsed light source with or without a lock-in amplifier detector can be used. For 2^{nd} scribe and 3^{rd} scribe alignment, reflective measurements in the visible region of the spectrum can be most suitable. Due to the feature size of the scribe lines in the range of 10-150 μm, the optical sensor are designed to have a resolution sufficient to adequately detect the scribe lines. The field of view of the sensor is such that 2 scribe lines of a type can be imaged simultaneously.

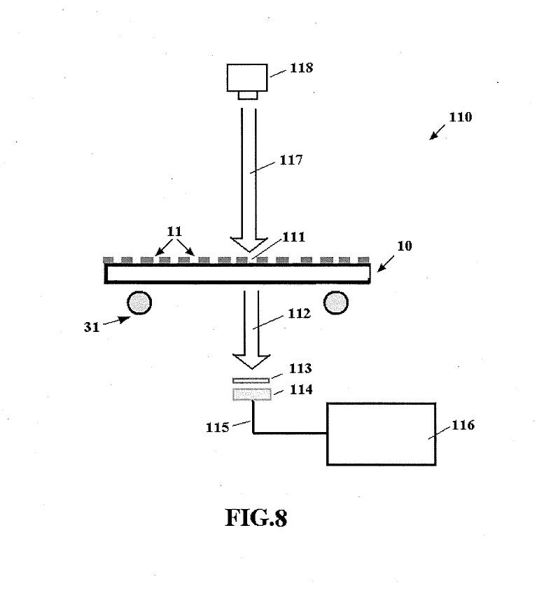

Referring to FIG. 8, with a through measurement set-up, optical sensor module 110 can implement optical scanning technique for the determination of scribing trenches 11 of photovoltaic module 10. Thereby, optical sensor module 110 can measure light absorption, diffuse or specular reflectance.

In some embodiments, optical sensor module 110 can include a photodetector with sufficient sensitivity in the suitable wavelength region.

In some embodiments, optical sensor module 110 can quantitatively compare the fraction of light that passes through a reference sample and scribing trenches 11 on a test sample to obtain the thickness information. Optical radiation 117 from optical source 118 can passed through a monochromator, which diffracts the light into a “rainbow” of wavelengths and outputs narrow bandwidths of this diffracted spectrum. Discrete frequencies can be transmitted through probe spot 111 on photovoltaic module 10. Then the intensity of the transmitted light 112 is measured with sensor 114, such as a photodiode or any other suitable light sensor. In processing unit 116 connected to sensor 114 by cable 115, the transmittance value for this wavelength is then compared with the transmission through a reference sample or the previous measurement to determine the position of scribing trenches 11. The monochromator can be placed in position 113 to further study the response on discrete frequencies on the analyzer side.

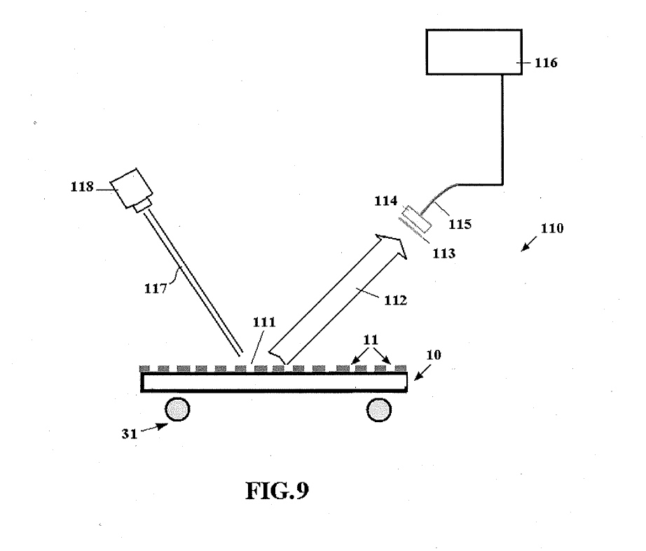

Referring to FIG. 9, optical sensor module 110 can include optical source 118 for generating optical radiation 117 to illuminate probe spot 111 on photovoltaic module 10.

Optical sensor module 110 can include sensor 114 for measuring the optical property of probe spot 111 to determine the position of scribing trenches 11.

In some embodiments, filter 113 can be positioned in front of sensor 114 to control the detected wavelength spectrum of incoming light 112. Cable 115 can be included to communicate the measurement result to processing unit 116 to obtain the information of the band gap and thickness of probe spot 111. Substrate 10 can be transported on conveyor 31.

In some embodiments, filter 113 can be not included in optical sensor module 110. In other embodiments, filter 113 can be positioned at the output side of optical source 118. Optical source 118 can be positioned at an angle ranging from 2 degree-90 degree with respect to substrate normal. Similarly sensor 114 can be positioned at an angle 2 degree-90 degree with respect to substrate normal. The system 100 can be in an enclosure to prevent ambient light from disrupting measurement. There can be attachments like a photo-eye that detects the presence or movement of photovoltaic module 10 to start the measurement.

In some embodiments, another attachment can be an infra-red pyrometer to measure the substrate temperature. Temperature information is essential to normalize any optical data that is being measured as material properties change with temperature. Optical source 118 and sensor 114 can be on mounted on gantry (130 in FIG. 3) and motorized to map the substrate.

After the positions of scribing trenches 11 are determined, metrology sensor (120 in FIG. 3) can be positioned to measure a measurement region with consistent layer sequence.

In some embodiments, the measurement region of the photovoltaic device can include measuring a transmitted or reflected signal from the measurement region of the photovoltaic device by any suitable non-contact sensor, such as Raman spectrometer, reflectometer, ellipsometer, XRF sensor, or transmission/absorption measurement device.

In some embodiments, the measurement region of the photovoltaic device can include contacting the measurement region of the photovoltaic device with any suitable contact sensor, such as a 4-point resistivity sensor.

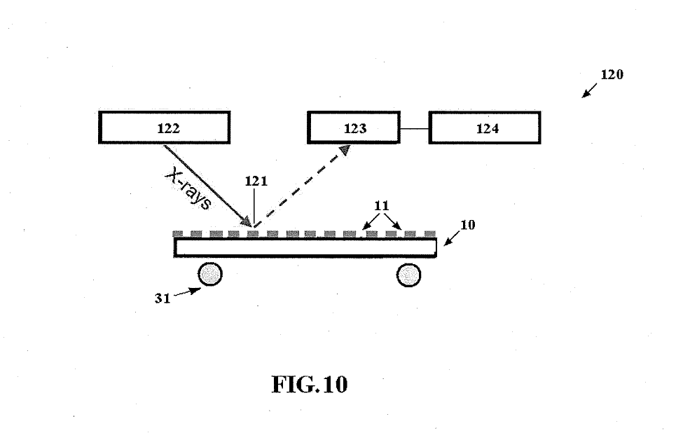

For example, referring to FIG. 10, metrology sensor module 120 can include X-ray fluorescence sensor 123 (XRF). X-ray fluorescence sensor 123 (XRF) can be an energy dispersive spectrometer (EDS). The energy dispersive spectrometer can detect the emission of characteristic “secondary” (or fluorescent) X-rays from probe spot 121 that has been excited by bombarding with high-energy X-rays (or gamma rays) from source 122. By analyzing the emission in processing unit 124, the energy dispersive spectrometer can provide layer compositional and element concentration as well as thickness information of the semiconductor device (e.g. photovoltaic module 10).

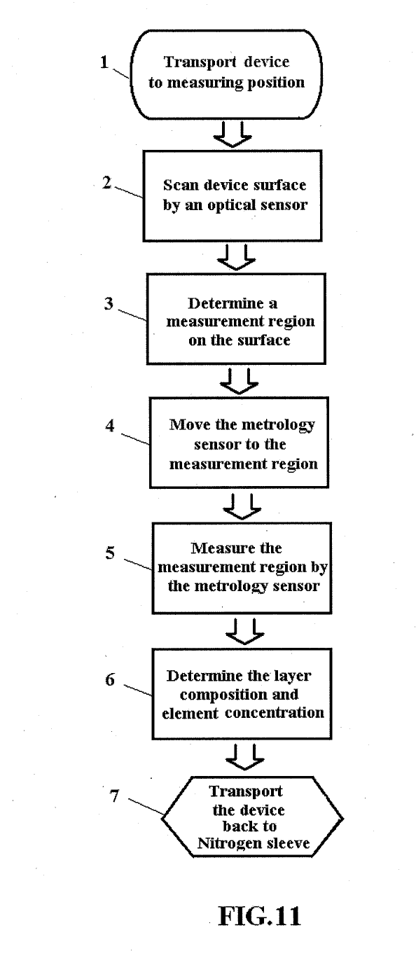

Referring to FIG. 11, semiconductor device manufacturing process can include: step (1) transporting the device to a measuring position; step (2) scanning the device surface by an optical sensor; step (3) determining a measurement region with consistent layer sequence; step (4) moving the metrology sensor to the measurement region; step (5) measuring the measurement region of the device; step (6) determining layer compositional and element concentration and/or thickness of the device; and step (7) transporting the device back to nitrogen sleeve for the following manufacturing process. Metrology system can further include a feed-back control loop for adjusting the semiconductor manufacturing process when it drifts from its purported baseline of layer compositional and element concentration.

In some embodiment, metrology system can adjust the measured location of the semiconductor material for spatially mapping a semiconductor material.

In some embodiment, metrology system can include spatial mapping function which can have additional value if the up or downstream process(es) can be tuned at the spatial levels.

In some embodiments, optical sensor module (110 in FIGS. 3, 8 and 9) can include an optical camera for visual inspection of the structure of the surface assembled to the measurement position. The camera can be used for visual finding of the middle between two lines in the structure of the sample and to position the measuring spot there. It can also be used for optical inspection of the sample surface.

In some embodiments, optical sensor module (110 in FIGS. 3, 8 and 9) can include at least two sensors and the measurements of the sensors can be averaged to determine the measurement position.

In some embodiments, the position identification module can be used in conjunction with a patterning recipe to determine the measurement position. The patterning recipe can include solar cell spacing, scribe gaps, or any suitable information. The patterning recipe can be pre-stored in the analysis module and real-time updated.

In some embodiments, the position identification module can include an optical source for generating an optical radiation to illuminate a region of a surface located at the object position, and a sensor for measuring the optical radiation reflected from a surface located at the object position. The sensor can include at least one charge-coupled device. The source can include a single-wavelength or wide band source.

In some embodiments, the position identification module can include a laser scanner with a signal analysis module. The laser scanner can generate a laser beam to scan the material surface. The signal analysis module can correlate the object position to a reflection of the laser beam.

In some embodiments, with the optical camera, a modified control-software for the measuring-system will be provided which includes following functionalities:

Automatic definition of measuring spot during scan;

Possibility of picture-acquisition for every metrology-measuring spot;

Move to coordinates, acquire picture and measure.

The camera can further acquire a picture of the region for the metrology measurement. The size of the acquired picture is sufficient to see both edges of the scribe region of at least one segment. In some embodiments, the camera can detect an entire scribe segment width corresponding to the segment where the metrology measurement will be taken. The optical inspection can be used to count, size and classify defects. Via the histogram of the picture, the edges of the cell can be identified and aligned on scanning table (80 in FIGS. 1 and 3).

Within the software optional for every coordinates during the scan, a picture can be saved to identify inhomogeneities of the surface afterwards. With this information the software calculates the position for the measuring spot, which is in the middle of the photovoltaic module. The software can move the sensors to a predefined position, acquire the XRF-spectra, and take a snapshot of the measuring spot.

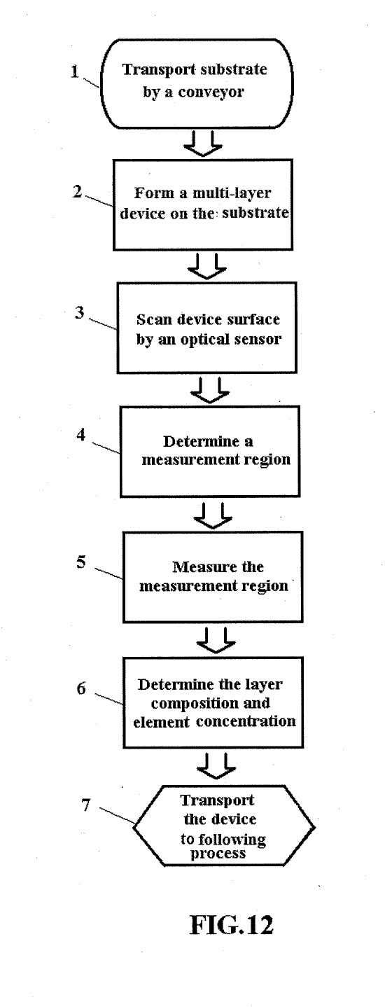

Referring to FIG. 12, photovoltaic device manufacturing process can include: step (1) transporting a substrate by a conveyor; step (2) forming a multi-layer device on the substrate; step (3) scanning the device surface by an optical sensor; step (4) determining a measurement region with consistent layer sequence; step (5) measuring the measurement region of the device; step (6) determining layer thickness, layer compositional, sheet resistivity and element concentration of the device; and step (7) transporting the device to the following manufacturing process. Metrology system can further include a feed-back control loop for adjusting the photovoltaic device manufacturing process when it drifts from its purported baseline of layer compositional and element concentration. The substrate can include glass.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A metrology scanner for analyzing a material surface comprising:
a position identification module configured to inspect a material surface to identify a measurement position; and
an analytical tool adjacent to the position identification configured to take an analytical measurement at the measurement position.

2. The metrology scanner of claim 1, wherein the position identification module and the analytical tool module are mounted on an adjustable mounting member to adjust the positions position identification module and analytical tool.

3. The metrology scanner of claim 1, wherein the position identification module and the analytical tool module are positioned on separate axes.

4. The metrology scanner of claim 1 further comprising a control module for reading an output of the position identification module and moving the analytical tool to the measurement position.

5. The metrology scanner of claim 1, wherein the position identification module is configured to scan a material surface and identify a measurement position proximate to a consistent material surface.

6. A metrology system for analyzing a material surface comprising:
an object position configured to position an object comprising a surface at least partially coated with a material.
a position identification module configured to inspect a material surface to identify a measurement position; and
an analytical tool adjacent to the position identification configured to take an analytical measurement at the measurement position and adjustable mounting member, wherein the analytical tool is mounted on the adjustable mounting member to adjust the positions of the analytical tool; and
a conveyor for transporting an object to the object position.

7. The metrology system of claim 6, wherein the position identification module are mounted on the adjustable mounting member to adjust the positions of the position identification module.

8. The metrology system of claim 6, wherein the position identification module are mounted on a second adjustable mounting member to adjust the positions of the position identification module.

9. The metrology system of claim 6 further comprising a control module for reading an output of the position identification module and positioning the analytical tool in a position to take a measurement in the measurement position.

10. The metrology system of claim 6, wherein the position identification module comprises an optical source that generates a probe beam capable of being directed at the measurement position.

11. The metrology system of claim 10, wherein the position identification module comprises a photodiode or photo-multiplier to convert an optical signal from the measurement position to electrical signals for processing.

12. The metrology system of claim 10, wherein the position identification module comprises a charge-coupled device with a resolution sufficient for inspecting the surface of an object in the object position.

13. The metrology system of claim 6, wherein the analytical tool comprises:
an X-ray source for directing X-rays to the measurement position of an object at the object position, wherein secondary X-rays can be emitted from the measurement position after an object positioned at the object position is excited by the X-ray source;
a detector for detecting the secondary X-rays emitted from the measurement position; and
an analyzing unit for analyzing the detector measurements to obtain an element concentration based on the secondary X-rays.

14. The metrology system of claim 13, wherein the detector comprises at least one detector selected from the group containing PIN diode, Si (Li) detector, Ge (Li) detector, silicon drift detector.

15. The metrology system of claim 13, wherein the analytical tool comprises an energy dispersive spectrometer.

16. The metrology system of claim 13, wherein the analytical tool comprises a wavelength dispersive spectrometer.

17. The metrology system of claim 6, wherein the analytical tool comprises at least one sensor selected from the group consisting Raman spectrometer, reflectometer, ellipsometer, transmission/absorption measurement device, or resistivity sensor.

18. The metrology system of claim 6, wherein the analytical tool is configured to take a measurement from a semiconductor-coated surface positioned at the measurement position.

19. The metrology system of claim 6, wherein the analytical tool is configured to take a measurement from a surface positioned at the measurement position, wherein the surface is at least partially coated with copper indium gallium diselenide.

20. The metrology system of claim 6, wherein the analytical tool is configured to take a measurement from a surface positioned at the measurement position, wherein the surface is at least partially coated with cadmium telluride.

21. The metrology system of claim 6, wherein the position identification module comprises an optical assembly, optical source, and optical sensor to collect optical reflection from a semiconductor device positioned at the object position.

22. The metrology system of claim 6, wherein the position identification module comprises an optical assembly, optical source, and optical sensor to collect the light emitted from an object positioned at the object position.

23. The metrology system of claim 6, wherein the position identification module comprises an optical assembly, optical source, and optical sensor to collect the light transmitted through an object positioned at the object position.

24. The metrology system of claim 6, wherein the position identification module comprises a spectrometer to parse light into component wavelengths.

25. The metrology system of claim 6 further comprising a feed-back control loop, wherein the system can adjust a material deposition process based on a measurement taken at the measurement position.

26. The metrology system of claim 6 further comprising an enclosure, wherein the first sensor module and the second sensor module are positioned within the enclosure.

27. The metrology system of claim 6, wherein the metrology system is configured to receive an object in a horizontal orientation from an inert atmosphere and return the object to the inert atmosphere for a following process upon completion of the measurements.

28. The metrology system of claim 6, wherein the metrology system is configured to receive an object in a horizontal orientation from a controlled atmosphere and return the object to the controlled atmosphere for a following process upon completion of the measurements, wherein the controlled atmosphere comprises nitrogen and argon.

29. The metrology system of claim 28, wherein the controlled atmosphere is temperature and moisture controlled.

30. The metrology system of claim 6, wherein the position identification module comprises at least two sensors and the measurements of the sensors are averaged to determine the measurement position.

31. The metrology system of claim 6, wherein the position identification module is used in conjunction with a patterning recipe to determine the measurement position.

32. The metrology system of claim 6, wherein the analytical tool comprises:
a source for generating a radiation to illuminate a region of a surface located at the object position;
a sensor for measuring the radiation reemitted from a surface located at the object position; and
a processing unit for analyzing the radiation measurement and outputting material information based on the radiation measurement.

33. The metrology system of claim 6, wherein the position identification module comprises:
an optical source for generating an optical radiation to illuminate a region of a surface located at the object position, the source comprising a single-wavelength or wide band source; and
a sensor for measuring the optical radiation reflected from a surface located at the object position, the sensor comprising at least one charge-coupled device.

34. The metrology system of claim 6, wherein the position identification module comprises a laser scanner with a signal analysis module, the laser scanner generating a laser beam to scan the material surface, the signal analysis module correlating the object position to a reflection of the laser beam.

35. A method of manufacturing a photovoltaic device comprising:
providing a first photovoltaic device layer on a substrate;
providing a second photovoltaic device layer adjacent to the first semiconductor layer, wherein at least one of the photovoltaic device layers is discontinuous;
inspecting a surface of the photovoltaic device layers to determine a measurement region with consistent layer sequence; and
measuring the measurement region of the photovoltaic device to obtain material property information of the photovoltaic device.

36. The method of claim 35 further comprising transporting the substrate on a conveyor.

37. The method of claim 35, wherein inspecting a surface of the photovoltaic device layers comprises:
generating an optical radiation to illuminate a region of the surface of the photovoltaic device layers;
measuring the absorption or reflection of the optical radiation in the photovoltaic device layers; and
analyzing the optical measurement to obtain the structural information of the photovoltaic device layers to determine the measurement region.

38. The method of claim 35, wherein measuring the measurement region of the photovoltaic device comprises obtaining at least one of layer thickness, layer composition, sheet resistivity and element concentration of the photovoltaic device.

39. The method of claim 35, wherein measuring the measurement region of the photovoltaic device comprises measuring a transmitted or reflected signal from the measurement region of the photovoltaic device by at least one sensor selected from the group consisting Raman spectrometer, reflectometer, ellipsometer, or transmission/absorption measurement device.

40. The method of claim 35, wherein measuring the measurement region of the photovoltaic device comprises contacting the measurement region of the photovoltaic device with a resistivity sensor.

41. The method of claim 35 further comprising transporting the photovoltaic device in an inert gas ambient.

42. The method of claim 35, wherein the photovoltaic device comprises copper indium gallium diselenide.

43. The method of claim 35, wherein the photovoltaic device comprises cadmium telluride.

44. The method of claim 35, wherein the photovoltaic device comprises at least two layers of semiconductor material and at least one layer is discontinuous.
